(19) United States
(12) Patent Application Publication
(10) Pub. No.: US 2026/0215220 A1
(43) Pub. Date: Jul. 23, 2026

(54) SEMICONDUCTOR DEVICE AND FABRICATION METHODS THEREOF

(71) Applicant: Yangtze Memory Technologies Co., Ltd., Wuhan (CN)

(72) Inventors: Huijie ZHU, Wuhan (CN); Ping MO, Wuhan (CN); Peng CHEN, Wuhan (CN); Zhong LV, Wuhan (CN)

(21) Appl. No.: 19/094,166

(22) Filed: Mar. 28, 2025

(30) Foreign Application Priority Data
Jan. 22, 2025 (CN) 202510098800.X

(51) Int. Cl. H01L 21/683; H01L 21/02; H01L 21/762; H01L 21/78

(52) U.S. Cl. CPC H10P 72/7402; H10P 54/00; H10P 90/123; H10W 10/011; H10W 10/10; H10P 72/7416

(57) ABSTRACT

Methods, devices, systems, and techniques for dissecting a semiconductor wafer into multiple semiconductor devices are provided. In one aspect, the semiconductor device includes a circuit layer and a substrate. The semiconductor device includes four side surfaces and one or more notches extending into a portion of at least one of the four side surfaces, where a side wall of the one or more notches includes microcracks extend into the circuit layer, and where a remaining portion of the at least one of the four side surfaces is substantially flat and is intersected by the at least one of the one or more notches along the first direction; a portion of one or more of the four side surfaces is substantially flat and extending from a first surface to a second surface of the semiconductor device that are opposite to each other along the first direction.

### CROSS-REFERENCE TO RELATED APPLICATIONS

This application claims priority to Chinese Patent Application No. 202510098800.X, filed on Jan. 22, 2025, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The peripheral circuits can include capacitors such as metal oxide metal capacitors (MOMCAP).

Due to the demand for cheaper memory devices with higher density, a memory device can be formed with increased stack thickness and a high degree of chip integration. The increasing number of metal layers and complex materials in each layer brings challenges during the packaging and cutting process. These complex materials and metal layers may pose challenges for cutting methods, resulting in poor edge quality of the memory device. For example, some cutting methods can cut through the complex materials but reduce wafer strength due to the introduction of edge defects, which may pose a significant risk and affect the mechanical properties of the final package of the memory device. Therefore, a cutting method during the fabrication of the memory device that can maintain high device quality and wafer strength is desirable.

### SUMMARY

The present disclosure describes methods, devices, systems and techniques for managing capacitor structures in three-dimensional (3D) semiconductor devices.

One aspect of the present disclosure features a method of forming a semiconductor device. The method includes providing a semiconductor wafer including a circuit layer and a substrate, where the circuit layer is stacked on the substrate along a first direction; forming one or more grooves along a second direction perpendicular to the first direction; and dissecting the semiconductor wafer along the first direction to divide the semiconductor wafer into semiconductor devices, where a first semiconductor device of the semiconductor devices includes four side surfaces, and a first groove of the one or more grooves splits into two notches of two adjacent semiconductor devices, where at least one of the four side surfaces is intersected by the at least one of the notches and is substantially flat, where at least a portion of the at least one of the four side surfaces extends from a first surface to a second surface of the corresponding semiconductor device along the first direction, and where a first side surface and a second side surface of the four side surfaces are opposite to each other along the second direction, and a third side surface and a fourth side surface of the four side surfaces are opposite to each other along the third direction.

In some implementations, the semiconductor wafer further includes dissecting lines extending along the second direction and a third direction perpendicular to the first direction and the second direction.

In some implementations, dissecting the semiconductor wafer further includes dissecting the circuit layer and the substrate along the dissecting lines.

In some implementations, forming the one or more grooves is based on performing laser grooving, and where the laser grooving includes focusing a laser beam with a first energy level on a surface of the circuit layer, the surface of the circuit layer being further away from the substrate along the first direction; and burning a portion of the circuit layer of the semiconductor wafer along the first direction with the laser beam.

In some implementations, a side wall of one or more grooves includes microcracks extend into the circuit layer along the second direction.

In some implementations, dividing the semiconductor wafer into semiconductor devices includes dissecting the semiconductor wafer along the first direction based on performing Stealth Dicing Before Grinding (SDBG).

In some implementations, performing the SDBG includes focusing a laser beam with a second energy level on the semiconductor wafer, where the laser beam focuses internally on the substrate of the semiconductor wafer, and where the second energy level of the laser beam is lower than the first energy level of the laser beam; and applying an external stress to the substrate of the semiconductor wafer through the laser beam to divide the semiconductor devices of the semiconductor wafer from each other.

In some implementations, forming the one or more grooves is based on performing blade grooving, and where the blade grooving includes removing a portion of the circuit layer along the first direction with a dicing blade, where the dicing blade cuts into the circuit layer of the semiconductor wafer and physically removes the portion of the circuit layer along the first direction.

In some implementations, the circuit layer includes chipped regions connected to the one or more grooves.

Another aspect of the present disclosure features a semiconductor device. The semiconductor device includes a circuit layer and a substrate, where the circuit layer is stacked on the substrate along a first direction, where the semiconductor device includes four side surfaces, and where a first side surface and a second side surface of the four side surfaces are opposite to each other along a second direction perpendicular to the first direction, and a third side surface and a fourth side surface of the four side surfaces are opposite to each other along a third direction perpendicular to the first direction and the second direction; one or more notches extending into a portion of at least one of the four side surfaces along the first direction, where a side wall of the one or more notches includes microcracks extend into the circuit layer along the second direction, and where a remaining portion of the at least one of the four side surfaces is substantially flat and is intersected by the at least one of the one or more notches along the first direction; and a portion of one or more of the four side surfaces is substantially flat and extending from a first surface to a second surface of the semiconductor device, where the first surface and the second surface of the semiconductor device are opposite to each other along the first direction.

In some implementations, a length of the one or more notches is greater than 20 μm along the second direction.

In some implementations, the side wall of the one or more notches includes an uneven surface.

In some implementations, the one or more notches extend though the circuit layer and into the substrate of the semiconductor device along the first direction.

In some implementations, a quantity of the microcracks on a first portion of the side wall of the one or more notches is greater than a quantity of the microcracks on a second portion of the side wall of the one or more notches, the first portion of the side wall of the one or more notches being closer to the first surface of the semiconductor device than the second portion of the side wall of the one or more notches along the first direction.

A further aspect of the present disclosure features a semiconductor device. The semiconductor device includes a circuit layer and a substrate, where the circuit layer is stacked on the substrate along a first direction, where the semiconductor device includes four side surfaces, and where a first side surface and a second side surface of the four side surfaces are opposite to each other along a second direction perpendicular to the first direction, and a third side surface and a fourth side surface of the four side surfaces are opposite to each other along a third direction perpendicular to the first direction and the second direction; one or more notches extending into a portion of at least one of the four side surfaces along the first direction, where a remaining portion of the at least one of the four side surfaces is substantially flat and is intersected by the at least one of the one or more notches along the first direction; and a portion of one or more of the four side surfaces is substantially flat and extending from a first surface to a second surface of the semiconductor device, where the first surface and the second surface of the semiconductor device are opposite to each other along the first direction.

In some implementations, the circuit layer includes chipped regions connected to the one or more notches.

In some implementations, a length of the one or more notches is in a range from 10 μm to 20 μm along the second direction.

In some implementations, a side wall of the one or more notches includes a substantially flat surface.

In some implementations, a slope of a first portion of the side wall of the one or more notches is greater than a slope of a second portion of the side wall of the one or more notches, the first portion of the side wall of the one or more notches being closer to the first surface of the semiconductor device than the second portion of the side wall of the one or more notches along the first direction.

In some implementations, the one or more notches extends into the circuit layer of the semiconductor device along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a perspective view of an example 3D semiconductor wafer.

FIG. 1B illustrates a top view of the hybrid cutting process of an example 3D semiconductor wafer.

FIG. 1C illustrates a cross-sectional view of two adjacent semiconductor device during the cutting process.

FIGS. 2A-2B illustrate cross-sectional views of example semiconductor devices.

FIG. 2C illustrates a top view of an example semiconductor device.

FIGS. 3A-3C illustrate an example process of fabricating a semiconductor device.

FIG. 3D illustrates a cross-sectional view of a semiconductor structure along the cut line AA′ of FIG. 3C.

FIGS. 4A-4G illustrate top view of one or more grooves on an example semiconductor wafer.

FIG. 5 illustrates a flow chart of an example process of manufacturing a semiconductor device.

FIG. 6 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

The present disclosure discloses techniques relating to semiconductor device fabrication methods. An example method includes providing a semiconductor wafer including a circuit layer and a substrate, where the circuit layer is stacked on the substrate along a first direction and forming one or more grooves along a second direction perpendicular to the first direction. The method also includes dissecting the semiconductor wafer along the first direction to divide the semiconductor wafer into semiconductor devices, where a first semiconductor device of the semiconductor devices includes four side surfaces, and a first groove of the one or more grooves splits into two notches of two adjacent semiconductor devices, where at least one of the four side surfaces is intersected by the at least one of the notches and is substantially flat, where at least a portion of the at least one of the four side surfaces extends from a first surface to a second surface of the corresponding semiconductor device along the first direction, and where a first side surface and a second side surface of the four side surfaces are opposite to each other along the second direction, and a third side surface and a fourth side surface of the four side surfaces are opposite to each other along the third direction.

Implementations of the present disclosure can provide one or more of the following technical advantages and/or benefits. First, the method includes a hybrid cutting process that can fabricate a high-quality semiconductor device with high wafer strength. Second, the one or more grooves between two adjacent semiconductor devices can assist in dissecting the semiconductor wafer by providing a stress concentration zone that allows for easy separation of the semiconductor devices. In other words, the addition of the one or more grooves can help improve the quality of the fabricated semiconductor device. Third, the dissecting process separates the semiconductor devices from each other by applying an external separation force from the substrate to maintain high wafer strength. Additionally, the stress concentration zone created by the one or more grooves also assists the propagation of the separation force from the substrate to the circuit layer. Therefore, the semiconductor device fabricated by the disclosed method can achieve high device quality with high wafer strength.

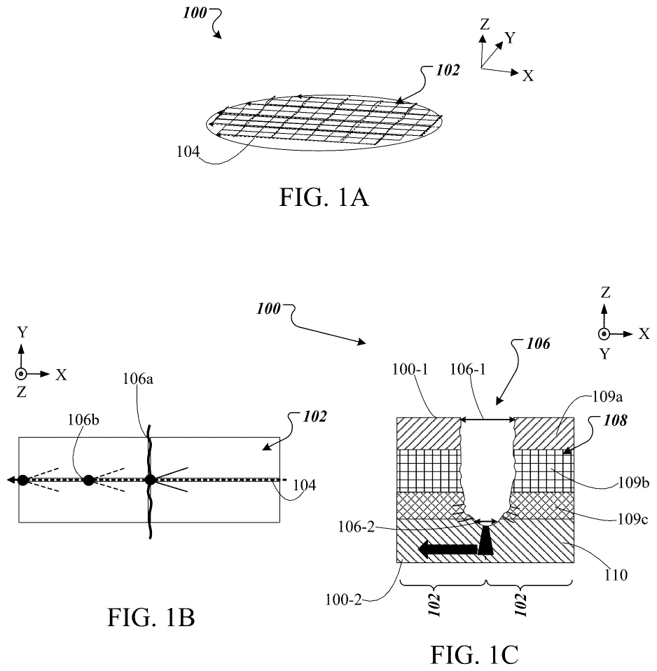

FIG. 1A illustrates a perspective view of an example 3D semiconductor wafer 100. The semiconductor wafer 100 can include semiconductor devices 102. The semiconductor wafer 100 can include a circuit layer (e.g., the circuit layer 108 in FIG. 1C) and a substrate (e.g., the substrate 110 in FIG. 1C). In some implementations, the circuit layer 108 can include multiple dielectric layers and metal layers stacked on top of each other along a vertical direction (e.g., the Z direction). In some implementations, the semiconductor device 102 can be a volatile memory device such as a dynamic random-access memory (DRAM). In some implementations, the semiconductor device 102 can be a video random-access memory (VRAM) or a non-volatile memory (NVM) device such as NAND flash memory or ferroelectric random-access memory (FeRAM). In some implementations, the semiconductor device 102 can be a peripheral circuit layer for different memory devices such as the volatile memory device and the non-volatile memory device. In some implementations, as shown in FIG. 1A, the semiconductor wafer 100 can include dissecting lines 104 extending along horizontal directions (e.g., the X direction and Y direction) perpendicular to the Z direction. In some implementations, the dissecting line 104 is between two adjacent semiconductor devices 102. The semiconductor device 102 of the semiconductor wafer 100 can be separated through a hybrid cutting process. In some implementations, the dissecting lines 104 can include test circuits that coupled to the circuit layer 108. The test circuit in the dissecting lines 104 can be used to test semiconductor device performance.

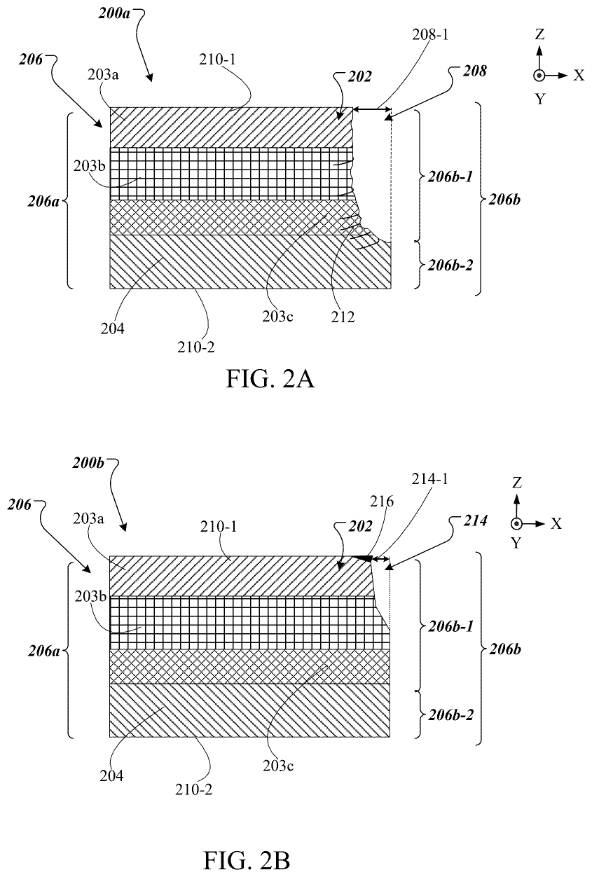

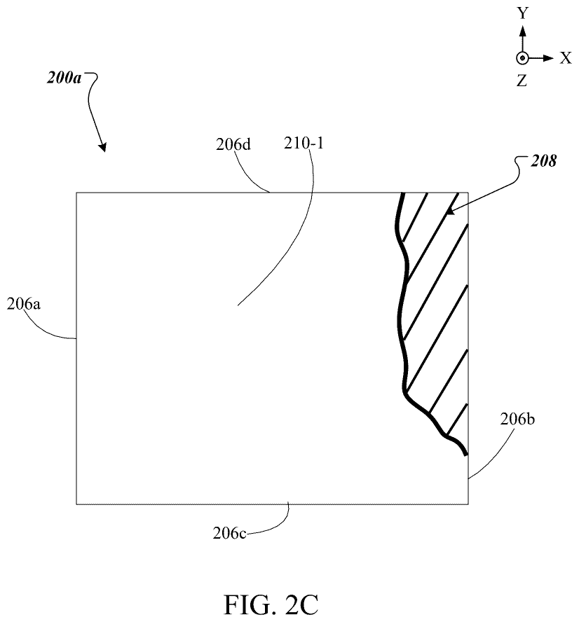

FIG. 1B illustrates a top view of the hybrid cutting process of an example 3D semiconductor wafer. As shown in FIG. 1B, the hybrid cutting process includes two-steps cutting process. In some implementations, the first step of the two-steps cutting process forms one or more grooves 106 (as shown in FIG. 1C) along a portion of the dissecting lines 104. The grooves 106 can have various shapes along the horizontal directions. For example, as shown in FIG. 1B, the groove 106a extends continuously along the Y direction and the groove 106b has a single hole on the dissecting line 104. In some implementations, the grooves 106 can be form by performing a laser grooving method (as shown in FIG. 2A) or a blade grooving method (as shown in FIG. 2B). The laser grooving method and the blade grooving method create grooves 106 that extend into the semiconductor wafer 100 from a first side 100-1 of the semiconductor wafer. For example, as shown in FIG. 1C, the groove 106 created by either the laser grooving method or the blade grooving method extends along the Z direction. The groove 106 extends from the first side 100-1 of the semiconductor wafer. In some implementations, the second step of the two-steps cutting process dissects the semiconductor wafer 100 along the Z direction through the dissecting lines 104 to divide the semiconductor wafer 100 into semiconductor devices 102. The dissecting of the semiconductor wafer 100 is achieved by performing Stealth Dicing Before Grinding (SDBG) method. The SDBG method separates the semiconductor wafer 100 from a second side 100-2 of the semiconductor wafer 100. For example, as shown in FIG. 1C, the first step of the hybrid cutting process is performed by either the laser grooving method or the blade grooving method that forms grooves 106 from the first side 100-1 of the semiconductor wafer. The grooves 106 extend along a portion of the dissecting lines 104. The second step of the hybrid cutting process is performed by the SDBG method which separates the semiconductor wafer 100 from the second side 100-2 of the semiconductor wafer 100 along the dissecting lines 104. The grooves 106 of the semiconductor wafer 100 is separated into two notches (e.g., the notch 208 of FIG. 2A) of the two adjacent semiconductor devices 102.

In some implementations, the separation of the semiconductor devices 102 can be achieved by performing a first method. The first method includes two steps. The first step forms grooves 106 along entire dissecting lines 104 by performing either the laser grooving method or the blade grooving method, where the grooves 106 extend into the semiconductor wafer 100 from the first side 100-1. The second step separates the semiconductor wafer from the second side 100-2 along the grooves 106 by performing the SDBG method. The first method can provide excellent separation capability of different materials, such as a thick metal layer or dielectric layer; however, the first method can lead to a reduction in wafer strength due to the formation of the grooves 106 along the entire dissecting lines 104. In some implementations, the separation of the semiconductor devices 102 can be achieved by performing a second method. The second method separates the semiconductor devices 102 by performing the SDBG method along the dissecting lines 104 to separate the semiconductor devices 102 from each other from the second side 100-2 of the semiconductor wafer 100. The second method can maintain high wafer strength; however, the second method has a poor separation capability of thick metal layer and dielectric layer. Compared to the first method and the second method, the hybrid cutting process described in this disclosure provides excellent separation capability of thick metal and dielectric layers by forming grooves 106 along a portion of the dissecting lines 104 from the first side 100-1 of the semiconductor wafer. The hybrid cutting process described in this disclosure also maintains high wafer strength after the separation of the semiconductor device 102, as the grooves 106 only extend along a portion of the dissecting lines 104.

FIG. 1C illustrates a cross-sectional view of two adjacent semiconductor device during the cutting process. As shown in FIG. 1C, the groove 106 is between two adjacent semiconductor device 102. The semiconductor device 102 can include a circuit layer 108 stacked on top of a substrate 110. The substrate 110 can be any suitable semiconductor substrate having any suitable semiconductor material, such as monocrystalline, polycrystalline or single crystalline semiconductor. For example, the substrate 110 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 110 can be removed from the semiconductor device 102 in a later process of manufacturing the semiconductor device 102. As shown in FIG. 1C, the circuit layer 108 can include a first conductive layer 109a, a second conductive layer 109b, and a third conductive layer 109c stacked on top of each other along the Z direction. In some implementations, the two adjacent conductive layers are separated by a dielectric layer. In some implementations, the dielectric layer can include a dielectric material, such as silicon oxide, silicon nitride, silicon oxynitride, or any combination thereof. In some implementations, the dielectric layer can include a high-K dielectric material, such as hafnium oxide, zirconium oxide, aluminum oxide, tantalum oxide, lanthanum oxide, or any combination thereof. In some implementations, a dielectric constant for the high-K dielectric materials (e.g., hafnium oxide) is greater than a dielectric constant of a dielectric material (e.g., Silicon oxide). For example, the high-K dielectric material (e.g., hafnium oxide) has a dielectric constant greater than 20 and a dielectric material (e.g., Silicon oxide) has a dielectric constant of 3.9. The conductive layers 109a, 109b, and 109c can include metal structures such as interconnect circuit of peripheral circuit surrounded by a dielectric material, test circuit coupled to the semiconductor device 102. FIG. 1C is for illustrate purpose only and the circuit layer 108 can include any number of conductive layers 109a, 109b, and 109c separated by the dielectric layer.

In some implementations, as shown in FIG. 1C, a length of a first end 106-1 of the groove 106 is greater than a length of the second end 106-2 of the groove 106 along the Y direction, the first end 106-1 is farther away from the substrate 110 than the second end 106-2 of the groove 106. In some implementations, the small length of the second end 106-2 of the groove 106 creates a stress concentration zone that assists the SDBG method. In some implementations, the SDBG method of cutting the semiconductor wafer include apply external stress in the substrate 110 through a laser source, where the laser source focuses in the substrate 110. In some implementations, the substrate 110 can be thinned down during the fabrication process to assist the SDBG method of cutting the semiconductor wafer 100.

FIG. 2A illustrates a cross-sectional view of example semiconductor device 200a. In some implementations, the semiconductor device 200a can be similar to, or same as, the semiconductor device 102 of FIG. 1A. The semiconductor device 200a includes a circuit layer 202 and a substrate 204. The circuit layer 202 is stacked on the substrate 204 along a vertical direction (e.g., the Z direction). FIG. 2C illustrates a top view of example semiconductor device 200a. As shown in FIG. 2C, the semiconductor device 200a includes four side surfaces 206, where a first side surface 206a and a second side surface 206b of the four side surfaces 206 are opposite to each other along a horizontal direction (e.g., the X direction) perpendicular to the Z direction. In some implementations, as shown in FIG. 2C, a third side surface 206c and a fourth side surface 206d of the four side surfaces 206 are opposite to each other along a second horizontal direction (e.g., the Y direction) perpendicular to the Z direction and the X direction.

As shown in FIGS. 2A and 2C, the semiconductor device 200a can also include one or more notches 208 extend into a portion of at least one of the four side surfaces 206 along the Z direction. In some implementations, a side wall of the one or more notches 208 includes microcracks 212 extend into the circuit layer 202 along the X direction. A remaining portion of the at least one of the four side surfaces 206 is substantially flat and is intersected by the at least one of the one or more notches 208 along the Z direction. For example, as shown in FIG. 2A, the notch 208 extend into a portion 206b-1 of the side surface 206b, where a remaining portion 206b-2 of the side surface 206b is substantially flat and is intersected by the portion 206b-1 of the side surface 206b. In some implementations, the one or more notches 208 is formed by performing laser grooving method and the substantially flat surface of the remaining portion 206b-2 of the side surface 206b is formed by performing the SDBG method.

In some implementations, a portion of one or more of the four side surfaces 206 is substantially flat and extending from a first surface 210-1 to a second surface 210-2 of the semiconductor device 200a, where the first surface 210-1 and the second surface 210-2 of the semiconductor device 200a are opposite to each other along the Z direction. For example, as shown in FIG. 2A, the side surface 206a includes a substantially flat surface that extends from the first surface 210-1 to the second surface 210-2 of the semiconductor device 200a. In some implementations, the substantially flat surface of the side surface 206a is formed by performing the SDBG method. In some implementations, the substantially flat surface of the side surface 206a and the substantially flat surface of the remaining portion 206b-2 are formed by performing a single SDBG step.

In some implementations, the circuit layer 202 can include a first conductive layer 203a, a second conductive layer 203b, and a third conductive layer 203c stacked on top of each other along the Z direction. In some implementations, the two adjacent conductive layers are separated by a dielectric layer. The dielectric layer can include a dielectric material, such as silicon oxide, silicon nitride, silicon oxynitride, or any combination thereof. It can also include a high-K dielectric material, such as hafnium oxide, zirconium oxide, aluminum oxide, tantalum oxide, lanthanum oxide, or any combination thereof. The dielectric constant for high-K dielectric materials (e.g., hafnium oxide) is greater than that of dielectric materials (e.g., silicon oxide). For example, the high-K dielectric material (e.g., hafnium oxide) has a dielectric constant greater than 20, while the dielectric material (e.g., silicon oxide) has a dielectric constant of 3.9. The conductive layers 203a, 203b, and 203c can include metal structures such as interconnect circuits of peripheral circuits surrounded by a dielectric material, and test circuits coupled to the semiconductor device 200a.

The substrate 204 can be any suitable semiconductor substrate having any suitable semiconductor material, such as monocrystalline, polycrystalline or single crystalline semiconductor. For example, the substrate 204 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 204 can be removed from the semiconductor device 200a in a later process of manufacturing the semiconductor device 200a.

In some implementations, the one or more notches 208 are formed by performing the laser grooving method where a high-power laser burns off a portion of the semiconductor device 200a from the first surface 210-1. As shown in FIG. 2A, a length of an end 208-1 of the one or more notches is greater than 20 um along the X direction and the side wall of the one or more notches includes an uneven surface. In some implementations, the one or more notches 208 extend though the circuit layer 202 and into the substrate 204 of the semiconductor device along the Z direction. In some implementations, a quantity of the microcracks 212 on a first portion of the side wall of the one or more notches 208 is greater than a quantity of the microcracks 212 on a second portion of the side wall of the one or more notches 208, the first portion of the side wall of the one or more notches 208 being closer to the second surface 210-2 of the semiconductor device 200a than the second portion of the side wall of the one or more notches 208 along the Z direction. For example, as shown in FIG. 2A, a density of the microcracks 212 of the one or more notches 208 closer to the second surfacer 210-2 is higher than a density of the microcracks 212 of the one or more notches 208 closer to the first surfacer 210-1. In some implementations, the uneven surface on the side wall of the one or more notches 208 and the microcracks 212 are results of the laser grooving, where the high-power laser burns off a portion of the circuit layer of the semiconductor device 200a from the first surface 210-1.

FIG. 2B illustrates a cross-sectional view of example semiconductor device 200b. In some implementations, the semiconductor device 200b can be similar to, or same as, the semiconductor device 200a of FIG. 2A except the one or more notches 214 of the semiconductor device 200b is formed by performing the blade grooving method. The semiconductor device 200b includes a circuit layer 202 and a substrate 204. The circuit layer 202 is stacked on the substrate 204 along a vertical direction (e.g., the Z direction). In some implementations, the semiconductor device 200b includes four side surfaces 206, where a first side surface 206a and a second side surface 206b of the four side surfaces 206 are opposite to each other along a horizontal direction (e.g., the X direction) perpendicular to the Z direction, as shown in FIG. 2A. In some implementations (not shown in FIG. 2B), a third side surface and a fourth side surface of the four side surfaces 206 are opposite to each other along a second horizontal direction (e.g., the Y direction) perpendicular to the Z direction and the X direction.

In some implementations, the semiconductor device 200b can also include one or more notches 214 extend into a portion of at least one of the four side surfaces 206 along the Z direction, where a remaining portion of the at least one of the four side surfaces 206 is substantially flat and is intersected by the at least one of the one or more notches 214 along the Z direction. For example, as shown in FIG. 2B, the notch 214 extend into a portion 206b-1 of the side surface 206b, where a remaining portion 206b-2 of the side surface 206b is substantially flat and is intersected by the portion 206b-1 of the side surface 206b. In some implementations, the one or more notches 214 is formed by performing blade grooving and the substantially flat surface of the remaining portion 206b-2 of the side surface 206b is formed by performing the SDBG method.

In some implementations, a portion of one or more of the four side surfaces 206 is substantially flat and extending from a first surface 210-1 to a second surface 210-2 of the semiconductor device 200b, where the first surface 210-1 and the second surface 210-2 of the semiconductor device 200b are opposite to each other along the Z direction. For example, as shown in FIG. 2B, the side surface 206a includes a substantially flat surface that extends from the first surface 210-1 to the second surface 210-2 of the semiconductor device 200b. In some implementations, the substantially flat surface of the side surface 206a is formed by performing the SDBG method. In some implementations, the substantially flat surface of the side surface 206a and the substantially flat surface of the remaining portion 206b-2 are formed by performing a single SDBG step.

In some implementations, the one or more notches 214 are formed by performing the blade grooving method where a blade physically remove a portion of the semiconductor device 200b from the first surface 210-1. In some implementations, the circuit layer 202 includes chipped regions 216 connected to the one or more notches 214. In some implementations, as shown in FIG. 1B, a length of an end 214-1 of the one or more notches 214 is in a range from 10 um to 20 um along the X direction. In some implementations, a side wall of the one or more notches 214 includes a substantially flat surface. In some implementations, a slope of a first portion 214a of the side wall of the one or more notches 214 is greater than a slope of a second portion 214b of the side wall of the one or more notches 214, the first portion 214a of the side wall of the one or more notches 214 being closer to the first surface 210-1 of the semiconductor device 200b than the second portion 214b of the side wall of the one or more notches 214 along the Z direction. For example, as shown in FIG. 2B, different slops of the first portion 214a and the second portion 214b of the side wall of the notch 214 forms a unique shape that matches the blade used during the blade grooving. In some implementations, the one or more notches 214 extends into the circuit layer 202 of the semiconductor device along the Z direction, where a depth of the one or more notches 214 is corresponding to the dimension of the blade. In some implementations, the substantially flat surface on the side wall of the one or more notches 214 and the chipped regions 216 are results of the blade grooving, where the blade physically removes a portion of the circuit layer of the semiconductor device 200a from the first surface 210-1.

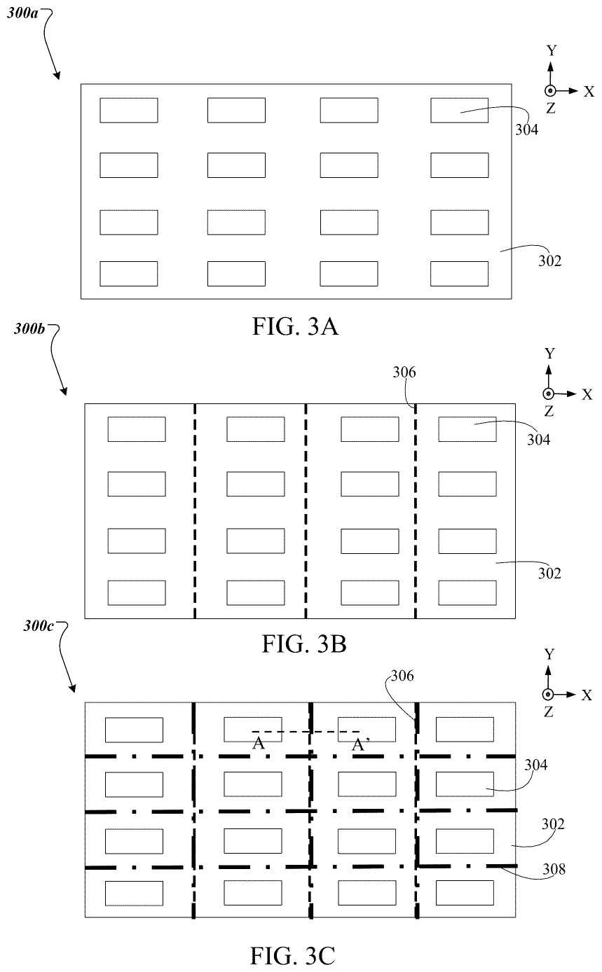

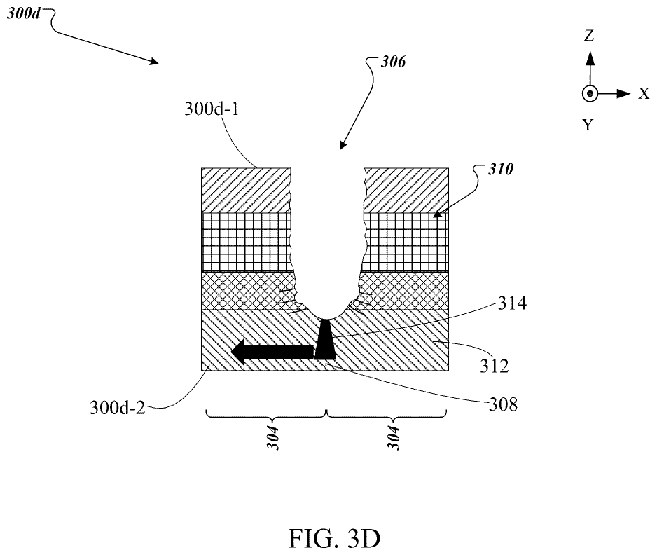

FIGS. 3A-3D illustrate an example process of fabricating a semiconductor device, such as the semiconductor device 200a as illustrated in FIG. 2A and the semiconductor device 200b as illustrated in FIG. 2B. FIGS. 3A-3C show top views of example semiconductor structures at various stages of the fabrication process.

FIG. 3A illustrates a semiconductor structure 300a. The semiconductor structure 300a includes a semiconductor wafer 302. The semiconductor wafer 302 can include a circuit layer and a substrate, where the circuit layer is stacked on the substrate along the vertical direction (e.g., the Z direction). The semiconductor wafer 302 also includes semiconductor devices 304. For example, as shown in FIG. 3A, the semiconductor devices 304 are spaced from each other along horizontal directions (e.g., the X direction and the Y direction) perpendicular to the Z direction.

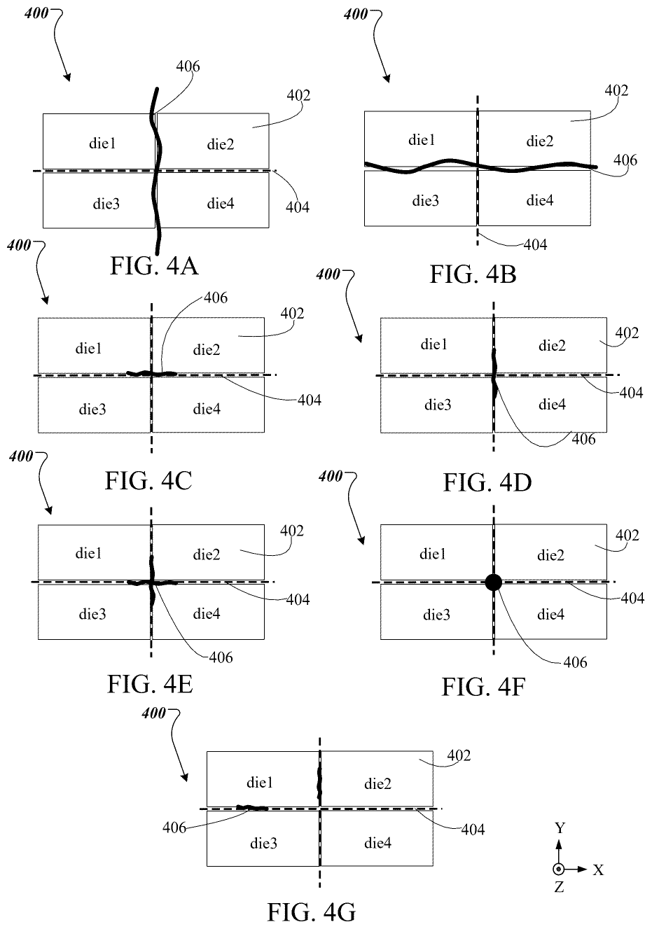

FIG. 3B illustrates a semiconductor structure 300b, which can be formed by etching a portion of the circuit layer along the Y direction to form one or more grooves 306. In some implementations, the one or more grooves 306 can be formed by performing the laser grooving method. The laser grooving method includes focusing a laser beam with a first energy level on a surface of the circuit layer and burning a portion of the circuit layer of the semiconductor wafer 302 along the Z direction with the laser beam. In some implementations, the one or more grooves 306 can be formed by performing the blade grooving method. The blade grooving method includes removing a portion of the circuit layer along the Z direction with a dicing blade, where the dicing blade cuts into the circuit layer of the semiconductor wafer 302 and physically removes the portion of the circuit layer along the Z direction. In some implementations, the one or more grooves 306 can assist the separating of the semiconductor devices 304 on the semiconductor wafer 302 from each other by providing a stress concentration zone at an end of the one or more grooves 306. The one or more grooves 306 can have various shapes and structures along the horizontal directions as shown in FIGS. 4A-4G .

FIGS. 4A-4G illustrate top view of one or more grooves on an example semiconductor wafer. FIGS. 4A-4G can be a part of the example process of fabricating a semiconductor device as illustrated by FIG. 3B. As shown in FIGS. 4A-4G the semiconductor wafer 400 can include a plurality of semiconductor devices 402 and dissecting lines 404 extending along horizontal directions (e.g., the X direction and the Y direction). The dissecting lines 404 separated the semiconductor devices 402 from each other along the Z directions. The one or more grooves 406 are formed during the fabrication process to divide the semiconductor devices 402 from each other, where the one or more grooves extends along a portion of the dissecting lines 404. In some implementations, the one or more grooves 406 can be similar to, or same as the one or more grooves 306 of FIG. 3B. The one or more grooves 406 can have various shapes and structures as shown in FIGS. 4A-4G . For example, as shown in FIG. 4A, the one or more grooves 406 can extend along continuously along the Y direction. As shown in FIG. 4B, the one or more grooves 406 can extend along continuously along the X direction. As shown in FIG. 4C, the one or more grooves 406 can extend along the X direction through a portion of the dissecting lines 404. As shown in FIG. 4D, the one or more grooves 406 can extend along the Y direction through a portion of the dissecting lines 404. As shown in FIG. 4E, the one or more grooves 406 can extend along both the X direction and the Y direction through a portion of the dissecting lines 404 and the one or more grooves 406 forms a cross structure on corners of the semiconductor devices 402. As shown in FIG. 4F, the one or more grooves 406 can have a circular structure on the dissecting lines 404, where the one or more grooves 406 locate at corners of the semiconductor devices 402. As shown in FIG. 4G, the one or more grooves 406 extend intermittently along the X direction and the Y direction through a portion of the dissecting lines 404. The shapes and structures of the one or more grooves 406 is not limited to the examples shown in FIGS. 4A-4G . For example, the one or more grooves 406 can have a combination of the various shapes and structures shown in FIGS, 4A-4G.

FIG. 3C illustrates a semiconductor structure 300c, which can be formed by dissecting the semiconductor wafer 302 along the first direction to divide the semiconductor wafer 302 into semiconductor devices 304. In some implementations, the semiconductor wafer 302 can include dissecting lines 308 extending along the X direction and the Y directions, where dissecting the semiconductor wafer 302 further includes dissecting the circuit layer and the substrate along the dissecting lines 308. In some implementations, the semiconductor wafer 302 is dissected by performing Stealth Dicing Before Grinding (SDBG) method. In some implementations, the one or more grooves 306 extend along a portion of the dissecting lines 308 and the SDBG method splits a groove of the one or more grooves 306 into two notches of two adjacent semiconductor devices 304. In some implementations, the SDBG method includes focusing a laser beam with a second energy level on the substrate of the semiconductor wafer 302 and applying an external stress to the substrate of the semiconductor wafer 302 through the laser beam to divide the semiconductor devices 304 from each other. In some implementations, the second energy level is lower than the first energy level of the laser beam. In some implementations, the external stress provides a transverse force to separate the semiconductor devices 304 from the substrate to the circuit layer. In some implementations, the stress concentration zone created by the one or more grooves 306 can assist the propagation of the transverse force from the substrate to the circuit layer to increase a separation force of the semiconductor devices 304. In some implementations, the dissecting lines 308 can include some test circuit that coupled to the semiconductor device 304, where the test circuit can be used to test the device performance of the semiconductor device 304.

FIG. 3D illustrates a cross-sectional view of a semiconductor structure 300d along the cut line AA′ of FIG. 3C. The semiconductor structure 300d can include circuit layers 310 stacked on top of a substrate 312. The one or more grooves 306 formed by performing either the laser grooving method or the blade grooving method extend from a first side 300d-1 of the semiconductor structure 300d. In some implementations, as shown in FIG. 3D, the one or more grooves 306 extend through the circuit layer 310 and into the substrate 312. The semiconductor devices 304 are separated by performing the SDBG method by focusing the laser beam 314 with the second energy level on the substrate 312 from the second side 300d-2 of the semiconductor structure 300d after the formation of the one or more grooves 306.

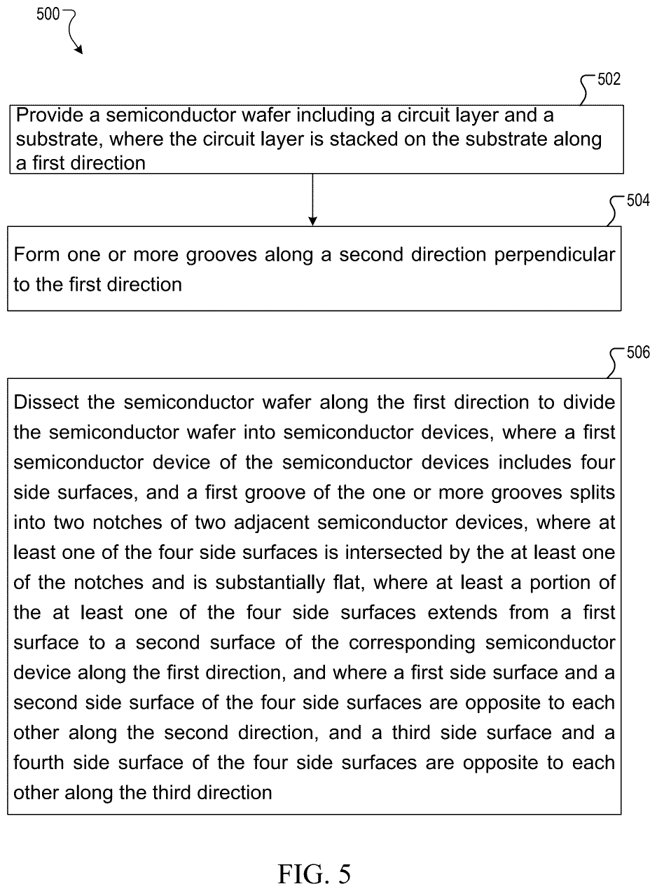

FIG. 5 illustrates a flow chart of an example process 500 of manufacturing a semiconductor structure. The process 500 can be performed to form a semiconductor device (e.g., the semiconductor device 200a of FIG. 2A and the semiconductor device 200b of FIG. 2B). The process 500 can be described in view of FIGS. 3A-3C . The process 500 can include one or more steps of the fabrication process of forming the semiconductor structures in FIGS. 3A-3C . It is understood that the operations shown in process 500 are not exhaustive and that other operations can be performed as well before, after, or between any of the illustrated operations. Further, some of the operations may be performed simultaneously, or in a different order than shown in FIG. 5.

At operation 502, a semiconductor wafer (e.g., the semiconductor wafer 302 of FIG. 3A) is provided. The semiconductor wafer includes a circuit layer (e.g., the circuit layer 202 of FIG. 2A) and a substrate (e.g., the substrate 204 of FIG. 2B), where the circuit layer is stacked on the substrate along a first direction (e.g., the Z direction).

At operation 504, one or more grooves (e.g., the one or more grooves 106 of FIG. 1C) along a second direction (e.g., the X direction) perpendicular to the first direction is formed.

At operation 506, the semiconductor wafer is dissected along the first direction to divide the semiconductor wafer into semiconductor devices (e.g., the semiconductor device 102 of FIG. 1A), where a first semiconductor device of the semiconductor devices includes four side surfaces (e.g., the side surfaces 206a and 206b of FIG. 2A), and a first groove of the one or more grooves splits into two notches (e.g., the notch 208 of FIG. 2A or the notch 214 of FIG. 2B) of two adjacent semiconductor devices, where at least one of the four side surfaces is intersected by the at least one of the notches and is substantially flat, where at least a portion of the at least one of the four side surfaces extends from a first surface (e.g., the first surface 210-1 of FIG. 2A) to a second surface (e.g., the second surface 210-2 of FIG. 2A) of the corresponding semiconductor device along the first direction, and where a first side surface (e.g., the side surface 206a of FIG. 2A) and a second side surface (e.g., the side surface 206b of FIG. 2A) of the four side surfaces are opposite to each other along the second direction, and a third side surface and a fourth side surface of the four side surfaces are opposite to each other along the third direction.

In some implementations, the semiconductor wafer further includes dissecting lines (e.g., the dissecting lines 104 of FIG. 1A) extending along the second direction and a third direction (e.g., the Y direction) perpendicular to the first direction and the second direction.

In some implementations, dissecting the semiconductor wafer further includes dissecting the circuit layer and the substrate along the dissecting lines.

In some implementations, forming the one or more grooves is based on performing laser grooving, and where the laser grooving includes focusing a laser beam with a first energy level on a surface of the circuit layer, the surface of the circuit layer being further away from the substrate along the first direction; and burning a portion of the circuit layer of the semiconductor wafer along the first direction with the laser beam.

In some implementations, a side wall of one or more grooves includes microcracks (e.g., the microcracks 212 of FIG. 2A) extend into the circuit layer along the second direction.

In some implementations, dividing the semiconductor wafer into semiconductor devices includes dissecting the semiconductor wafer along the first direction based on performing Stealth Dicing Before Grinding (SDBG).

In some implementations, performing the SDBG includes focusing the laser beam with a second energy level on the semiconductor wafer, where the laser beam focuses internally on the substrate of the semiconductor wafer, and where the second energy level of the laser beam is lower than the first energy level of the laser beam; and applying an external stress to the substrate of the semiconductor wafer through the laser beam to divide the semiconductor devices of the semiconductor wafer from each other.

In some implementations, forming the one or more grooves is based on performing blade grooving, and where the blade grooving includes removing a portion of the circuit layer along the first direction with a dicing blade, where the dicing blade cuts into the circuit layer of the semiconductor wafer and physically remove the portion of the circuit layer along the first direction.

In some implementations, the circuit layer includes chipped regions (e.g., the chipped regions 216 of FIG. 2B) connected to the one or more grooves.

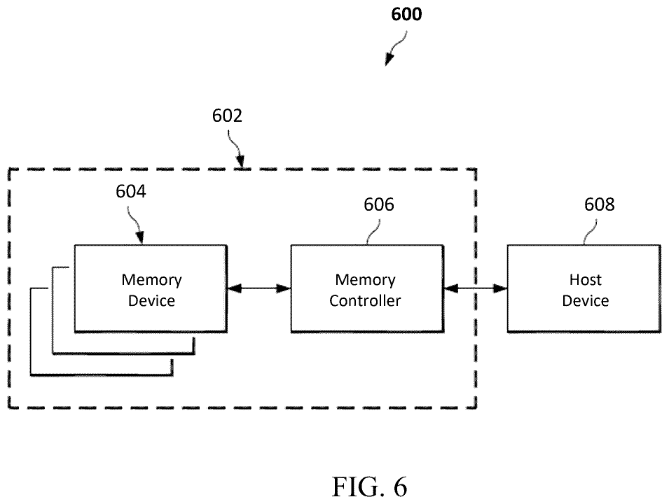

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as 3D memory device depicted in FIGS. 2A-2B. In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method of forming a semiconductor device, comprising:
providing a semiconductor wafer comprising a circuit layer and a substrate, wherein the circuit layer is stacked on the substrate along a first direction;
forming one or more grooves along a second direction perpendicular to the first direction; and
dissecting the semiconductor wafer along the first direction to divide the semiconductor wafer into semiconductor devices, wherein a first semiconductor device of the semiconductor devices comprises four side surfaces, and a first groove of the one or more grooves splits into two notches of two adjacent semiconductor devices,
wherein at least one of the four side surfaces is intersected by the at least one of the notches and is substantially flat, wherein at least a portion of the at least one of the four side surfaces extends from a first surface to a second surface of the corresponding semiconductor device along the first direction, and wherein a first side surface and a second side surface of the four side surfaces are opposite to each other along the second direction, and a third side surface and a fourth side surface of the four side surfaces are opposite to each other along a third direction, the third direction being perpendicular to the first direction and the second direction.

2. The method of claim 1, wherein the semiconductor wafer further comprises dissecting lines extending along the second direction and a third direction perpendicular to the first direction and the second direction.

3. The method of claim 2, wherein dissecting the semiconductor wafer further comprises dissecting the circuit layer and the substrate along the dissecting lines.

4. The method of claim 1, wherein forming the one or more grooves is based on performing laser grooving, and wherein the laser grooving comprises:
focusing a laser beam with a first energy level on a surface of the circuit layer, the surface of the circuit layer being further away from the substrate along the first direction; and
burning a portion of the circuit layer of the semiconductor wafer along the first direction with the laser beam.

5. The method of claim 4, wherein a side wall of one or more grooves comprises microcracks extending into the circuit layer along the second direction.

6. The method of claim 1, wherein dividing the semiconductor wafer into semiconductor devices comprises dissecting the semiconductor wafer along the first direction based on performing Stealth Dicing Before Grinding (SDBG).

7. The method of claim 6, wherein performing the SDBG comprises:
focusing a laser beam with a second energy level on the semiconductor wafer, wherein the laser beam focuses internally on the substrate of the semiconductor wafer, and wherein the second energy level of the laser beam is lower than the first energy level of the laser beam; and
applying an external stress to the substrate of the semiconductor wafer through the laser beam to divide the semiconductor devices of the semiconductor wafer from each other.

8. The method of claim 7, wherein forming the one or more grooves is based on performing blade grooving, and wherein the blade grooving comprises:
removing a portion of the circuit layer along the first direction with a dicing blade, wherein the dicing blade cuts into the circuit layer of the semiconductor wafer and physically removes the portion of the circuit layer along the first direction.

9. The method of claim 7 wherein the circuit layer comprises chipped regions connected to the one or more grooves.

10. A semiconductor device, comprising:
a circuit layer and a substrate, wherein the circuit layer is stacked on the substrate along a first direction, wherein the semiconductor device comprises four side surfaces, and wherein a first side surface and a second side surface of the four side surfaces are opposite to each other along a second direction perpendicular to the first direction, and a third side surface and a fourth side surface of the four side surfaces are opposite to each other along a third direction perpendicular to the first direction and the second direction; and
one or more notches extending into a portion of at least one of the four side surfaces along the first direction, wherein a side wall of the one or more notches comprises microcracks extending into the circuit layer along the second direction, and wherein a remaining portion of the at least one of the four side surfaces is substantially flat and is intersected by the at least one of the one or more notches along the first direction,
wherein a portion of one or more of the four side surfaces is substantially flat and extending from a first surface to a second surface of the semiconductor device, and wherein the first surface and the second surface of the semiconductor device are opposite to each other along the first direction.

11. The semiconductor device of claim 10, wherein a length of the one or more notches is greater than 20 μm along the second direction.

12. The semiconductor device of claim 10, wherein the side wall of the one or more notches comprises an uneven surface.

13. The semiconductor device of claim 10, wherein the one or more notches extend though the circuit layer and into the substrate of the semiconductor device along the first direction.

14. The semiconductor device of claim 10, wherein a quantity of the microcracks on a first portion of the side wall of the one or more notches is greater than a quantity of the microcracks on a second portion of the side wall of the one or more notches, the first portion of the side wall of the one or more notches being closer to the first surface of the semiconductor device than the second portion of the side wall of the one or more notches along the first direction.

15. A semiconductor device, comprising:
a circuit layer and a substrate, wherein the circuit layer is stacked on the substrate along a first direction, wherein the semiconductor device comprises four side surfaces, and wherein a first side surface and a second side surface of the four side surfaces are opposite to each other along a second direction perpendicular to the first direction, and a third side surface and a fourth side surface of the four side surfaces are opposite to each other along a third direction perpendicular to the first direction and the second direction; and
one or more notches extending into a portion of at least one of the four side surfaces along the first direction, wherein a remaining portion of the at least one of the four side surfaces is substantially flat and is intersected by the at least one of the one or more notches along the first direction,
wherein a portion of one or more of the four side surfaces is substantially flat and extending from a first surface to a second surface of the semiconductor device, and wherein the first surface and the second surface of the semiconductor device are opposite to each other along the first direction.

16. The semiconductor device of claim 15, wherein the circuit layer comprises chipped regions connected to the one or more notches.

17. The semiconductor device of claim 15, wherein a length of the one or more notches is in a range from 10 μm to 20 μm along the second direction.

18. The semiconductor device of claim 15, wherein a side wall of the one or more notches comprises a substantially flat surface.

19. The semiconductor device of claim 18, wherein a slope of a first portion of the side wall of the one or more notches is greater than a slope of a second portion of the side wall of the one or more notches, the first portion of the side wall of the one or more notches being closer to the first surface of the semiconductor device than the second portion of the side wall of the one or more notches along the first direction.

20. The semiconductor device of claim 15, wherein the one or more notches extends into the circuit layer of the semiconductor device along the first direction.
